(19) United States
(12) Patent Application Publication
(10) Pub. No.: US 2006/0237802 A1
(43) Pub. Date: Oct. 26, 2006

(54) Method for improving SOG process

(75) Inventors: Lee-Jen Chen, Taipei (TW); Chin-Ta Su, Erlun Shiang (TW); Kuang-Wen Liu, Zhudong Town (TW); Chien-Hung Lu, Kaohsiung City (TW); Shing-Ann Luo, Toufen Town (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Macronix International Co., Ltd.

(21) Appl. No.: 11/110,862

(22) Filed: Apr. 21, 2005

(51) Int. Cl. H01L 29/76

(52) U.S. Cl. 257/408

(57) ABSTRACT

A method for forming a memory device includes providing a substrate, providing a plurality of features on the substrate, and forming a silicon-rich dielectric layer over the features. An inter-layer dielectric (ILD) or inter-metal dielectric (IMD) layer may be formed by a spin-on-glass (SOG) process on the silicon-rich dielectric layer, the silicon-rich dielectric layer preventing diffusion of a solvent used in the SOG process.

### DESCRIPTION OF THE INVENTION

1. Field of the Invention

This invention is in general related to a method of manufacturing semiconductor devices and, more particularly, to a method for improving a silicon-on-glass (SOG) process and a device manufactured according to the method.

2. Background of the Invention

Non-volatile memory devices have been widely used for storing information that does not require frequent modifications. Examples of such memory devices include read only memory (ROM), programmable ROM (PROM), erasable programmable ROM (EPROM), electrically erasable programmable ROM (EEPROM), and flash EEPROM.

Non-volatile memory devices generally store and retain electric charges, which represent information. For example, an EPROM may include a number of floating gate memory cells each including a charge trapping layer for retaining electric charge representing a datum. FIG. 1A shows the structure of an example of a conventional floating gate memory cell 100 formed on a semiconductor substrate 10. Memory cell 100 includes diffusion regions 102 and 104 formed in substrate 10 and spaced apart from each other, defining a channel 106 therebetween. A first dielectric layer 108 is formed over channel 106, a charge trapping layer 110 is formed over first dielectric layer 108, a second dielectric layer 112 is formed over charge trapping layer 110, and a gate 114 formed over second dielectric layer 112. First dielectric layer 108 may comprise a tunnel oxide. Second dielectric layer 112 may comprise silicon oxide or an ONO (oxide-nitride-oxide structure). Charge trapping layer 110 may comprise polysilicon or silicon nitride.

By applying bias voltages to gate 114 and diffusion regions 102 and 104, charges may tunnel into charge trapping layer 110, thereby programming memory cell 100, or may be pulled out of charge trapping layer 110, thereby erasing memory cell 100.

During programming of memory cell 100, charges such as holes or electrons tunnel through first dielectric layer 108 or second dielectric layer 112 and are stored in charge trapping layer 110. The charge stored in charge trapping layer 110 changes a threshold voltage for reading memory cell 100, which indicates whether a bit of “0” or “1” has been stored in memory cell 100.

To isolate memory cell 100 from other devices or metal contacts subsequently formed for providing contacts to gate 114 and diffusion regions 102 and 104, an inter-layer dielectric (ILD) 116 is used to fill gaps between memory cell 100 and the other devices. ILD 116 also serves as a low-dielectric-constant material for electrically isolating the metal contacts and memory cell 100. Most commonly, ILD 116 is formed of boro-phospho-silicate glass (BPSG) by a chemical vapor deposition (CVD) process. The BPSG CVD process is facilitated by being performed at high temperatures. As an alternative, a spin-on-glass (SOG) process, which requires only low temperatures, may be used to form ILD 116. The SOG process involves spinning onto a substrate a solution dissolving a mixture of SiO2 and dopants (such as boron or phosphorous) and curing the SOG to evaporate the solvent in the solution. Undesirably, during the curing process, the solvent may diffuse into the neighboring layers. For example, in FIG. 1A, when ILD 116 formed of SOG is cured, the solvent in the solution may diffuse into charge trapping layer 110, thereby deteriorating the performance of memory cell 100. To prevent such diffusion of the solvent, a liner layer 118 may be provided between ILD 116 and memory cell 100, as shown in FIG. 1A.

Similarly, in a memory device that utilizes multiple layers of metal contacts isolated from one another by inter-metal dielectric (IMD) layers, such IMD layers may be formed from SOG and oxide liner layers may be used to prevent solvent diffusion into neighboring layers, which diffusion also deteriorates the performance of the memory device. For example, FIG. 1B shows a memory device 200 formed on a substrate 202. Memory device 200 includes first metal contacts 204 and second metal contacts 206 isolated from first metal contacts 204 by an IMD layer 208. IMD layer 208 may be formed from SOG. A liner layer 210 between IMD layer 208 and first metal contacts 204 prevents solvent diffusion when IMD layer 208 is cured.

Conventionally, liner 118 or 210 comprises silicon dioxide (SiO₂), which may be formed by a plasma enhanced chemical vapor deposition (PECVD) process using a gas combination of SiH₄ and N₂O or a gas combination of tetraethylorthosilicate (TEOS) and O₂ or O₃. However, a problem with SiO₂ as oxide liner 118 or 210 is that, because the solvent dissolving the SOG used for forming ILD 116 or IMD 208 generally contain a high concentration of hydrogen to achieve a low dielectric constant of ILD 116 or IMD 208, the hydrogen atoms in the solvent may diffuse through liner 118 or 210 formed of SiO₂ into underlying layers such as charge trapping layer 110 or substrate 10 or 202. As a result of the hydrogen diffusion, memory cell 100 or memory device 200 may lose charge stored therein and may exhibit a poor data retention property.

Memory devices similar to memory cell 100 or memory device 200 were manufactured on a silicon wafer and the data retention property thereof was measured and is illustrated in FIG. 2 as compared to a standard requirement. In FIG. 2, the data retention property of a memory cell is reflected by a change of threshold voltage of the memory cell after 10,000 reading cycles. As shown in FIG. 2, the threshold voltage of memory cell 100 after 10,000 reading cycles changes by 1.2V, while the standard requires that the threshold voltage change be no greater than 0.6V.

To avoid the loss of information, memory cell 100 or memory device 200 must be refreshed before charge stored therein is lost, and power consumption increases as a frequency of refreshing increases. Therefore, it is important that memory cell 100 or memory device 200 be able to retain the stored charge as long as possible.

U.S. Pat. No. 5,805,013 to Ghneim et al. discloses the release of hydrogen atoms from their bonding sites whenever they are subjected to temperatures over a critical level. Ghneim et al. further discloses a method for reducing hydrogen diffusion into a floating gate (the charge trapping layer) of a memory cell by keeping temperatures in the process steps of depositing dielectric layers around the floating gate and all subsequent process steps below a critical temperature. Particularly, in Ghneim et al., hydrogen-containing dielectrics and all subsequent dielectrics/conductors are formed below 380° C., and in most instances below 350° C.

Although the low temperature processing steps disclosed in Ghneim et al. may reduce hydrogen diffusion into the charge trapping layer of a memory cell, a reliability of the memory cell thus formed may nevertheless be deteriorated because of poor qualities of materials formed during subsequent processing steps due to the low processing temperatures.

### SUMMARY OF THE INVENTION

Consistent with the present invention, there is provided a method for forming a memory device that includes providing a substrate, providing a plurality of features on the substrate, and forming a silicon-rich dielectric layer over the features.

Consistent with the present invention, there is provided a method for forming a semiconductor device that includes providing a substrate and forming a memory array including a plurality of memory cells over the substrate. Each of the memory cells is formed by providing at least one feature over the substrate and forming a layer of silicon-rich dielectric over the at least one feature. The method further includes depositing a layer of spin-on-glass to cover at least a portion of the layer of silicon-rich dielectric.

Consistent with the present invention, there is provided a semiconductor device that includes a substrate and a memory cell. The memory cell includes a feature over the substrate and a silicon-rich dielectric layer over the feature.

Consistent with the present invention, there is provided a semiconductor device that includes a substrate and a memory array including a plurality of memory cells over the substrate. Each memory cell includes a feature over the substrate and a layer of silicon-rich dielectric over the feature. The device further includes a layer of spin-on-glass over the layer of silicon-rich dielectric.

Additional features and advantages of the invention will be set forth in part in the description which follows, and in part will be obvious from the description, or may be learned by practice of the invention. The features and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings,

FIG. 1A shows an example of a conventional non-volatile memory cell;

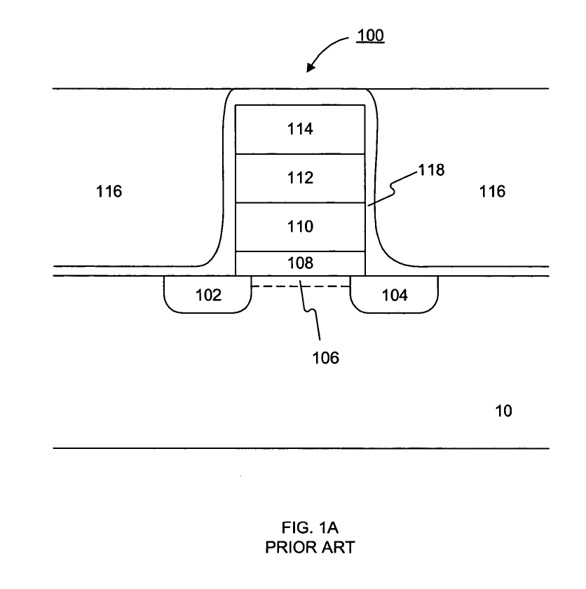

FIG. 1B shows an example of a conventional memory device;

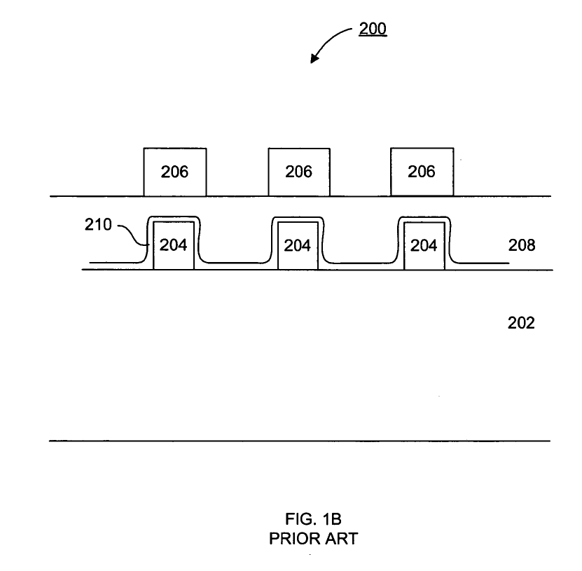

FIG. 2 graphically illustrates a data retention property of the memory cell of FIG. 1A as compared to a standard requirement;

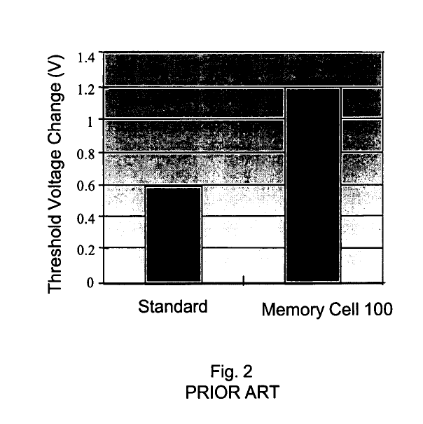

FIG. 3A shows a memory device consistent with a first embodiment of the present invention;

FIG. 3B shows a memory device consistent with a second embodiment of the present invention;

FIG. 4 graphically illustrates data retention properties of memory devices manufactured using a method consistent with the present invention as compared to standard requirements; and

FIG. 5 shows a memory array consistent with the present invention.

### DESCRIPTION OF THE EMBODIMENTS

Reference will now be made in detail to embodiments of the invention, examples of which are illustrated in the accompanying drawings. Wherever possible, the same reference numbers will be used throughout the drawings to refer to the same or like parts.

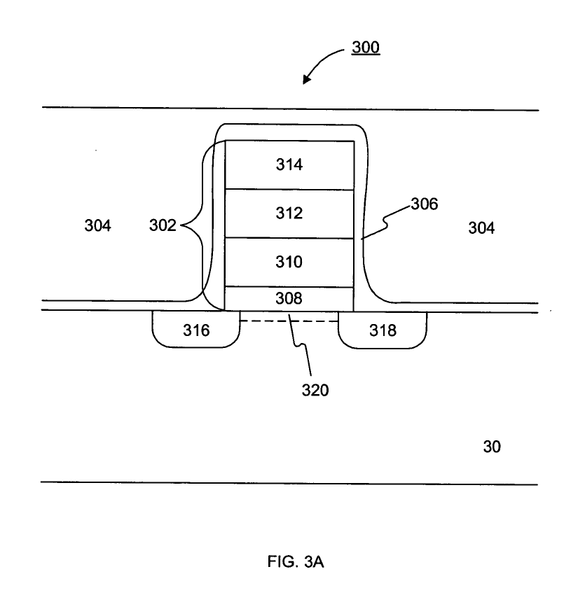

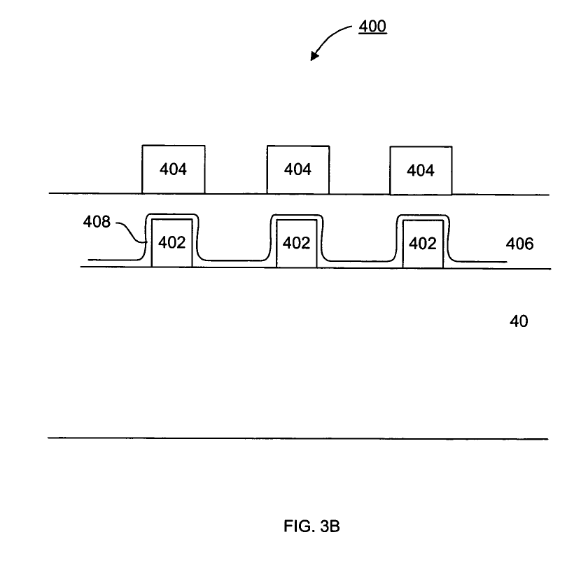

Consistent with the present invention, there is provided a novel non-volatile memory device that includes a silicon-rich layer of liner under an inter-layer dielectric (ILD) layer or an inter-metal dielectric (IMD) layer formed from spin-on glass (SOG), for preventing the diffusion of hydrogen contained in the solution of SOG. FIGS. 3A and 3B show non-volatile memory devices consistent with the present invention.

Referring to FIG. 3A, a memory device 300 consistent with a first embodiment of the present invention is formed on a semiconductor substrate 30 and may include features 302 (only one of which is shown) formed on semiconductor substrate 30. An ILD layer 304 is formed over substrate 30 and features 302 for providing insulation and filling in gaps between substrate 30 and features 302 and other devices or features on substrate 30. ILD layer 304 may be formed by spinning-on an SOG solution and curing the same. A dielectric liner 306 is formed between ILD layer 304 and substrate 30 and features 302 to prevent the diffusion of hydrogen contained in the SOG solution. ILD layer 304 may be formed on a portion (not shown) or a whole of dielectric liner 306.

Features 302 may include any suitable structure composing non-volatile memory device 300 such as gate structures or metal contacts. For example, as shown in FIG. 3A, if memory device 300 includes an array of floating-gate memory cells, features 302 may be multi-layered gate structures each including, e.g., a first dielectric layer 308 over substrate 30, a charge trapping layer 310 over first dielectric layer 308, a second dielectric layer 312 over charge trapping layer 310, and a gate 314 over second dielectric layer 312. First dielectric layer 308 and second dielectric layer 312 may each comprise an oxide such as silicon dioxide. Charge trapping layer 310 may comprise silicon nitride or polysilicon. Gate 314 may comprise a metal. As shown in FIG. 3A, memory device 300 may further include diffusion regions 316 and 318 formed in substrate 30 and on the sides of the corresponding feature 302, where diffusion regions 316 and 318 are spaced apart from each other and define a channel 320 therebetween.

Consistent with the present invention, dielectric liner 306 is silicon-rich, and may be formed by chemical vapor deposition (CVD) to comprise a silicon-rich oxide, wherein a ratio of the number of silicon atoms to the number of oxygen atoms in the silicon-rich oxide is higher than that in SiO₂. In one aspect, the ratio is higher than 1:1. As a result, dielectric liner 306 contains a large number of dangling silicon bonds. During a subsequent step of forming ILD layer 304, the dangling silicon bonds will capture and bond with hydrogen atoms and prevent the hydrogen atoms from entering into features 302 or substrate 30. Dielectric liner 306 formed of silicon-rich oxide may also act as a barrier between features 302 and ILD layer 304 for preventing the diffusion of the moisture or the solvent included in the SOG solution for forming of ILD layer 304. Therefore, a retention time of charges stored in memory device 300, e.g., in trapping layer 310, is increased. Also, by forming dielectric liner 306 as a silicon-rich oxide, it is unnecessary to maintain a low temperature for subsequent processes such as the process of forming ILD layer 304.

Similarly, in a memory device that utilizes multiple layers of metal contacts isolated from one another by inter-metal dielectric (IMD) layers, such IMD layers may be formed from SOG, and silicon-rich oxide liner layers may be used to prevent solvent diffusion into neighboring layers. For example, FIG. 3B shows a memory device 400 consistent with a second embodiment of the present invention. Memory device 400 is formed on a semiconductor substrate 40. Memory device 400 may include circuit elements (not shown), such as transistors or capacitors, formed in semiconductor substrate 40. Memory device 400 may further include a plurality of first metal contacts 402 and a plurality of second metal contacts 404 for providing electrical contacts to the circuit elements. An IMD layer 406 electrically isolates first metal contacts 402 from second metal contacts 404. IMD layer 406 also fills in gaps between substrate 40 and first metal contacts 402 and other devices or features on substrate 40. IMD layer 406 may be formed by spinning-on an SOG solution and curing the same. A silicon-rich dielectric liner 408 is formed between IMD layer 406 and substrate 40 and first metal contacts 402 to prevent the diffusion of hydrogen contained in the SOG solution. IMD layer 406 may be formed on a portion (not shown) or a whole of dielectric liner 408.

In one aspect, dielectric liner 408 is a silicon-rich oxide layer, wherein a ratio of the number of silicon atoms to the number of oxygen atoms is greater than 1:1. Consequently, because of the silicon dangling bonds in silicon-rich oxide liner 408, hydrogen atoms contained in the solvent of the SOG for forming IMD layer 406 are prevented from entering into first metal contacts 402 or substrate 40.

Silicon-rich oxide has a higher refractive index and extinction coefficient as compared to SiO₂. For example, liner 306 or 408 formed of silicon-rich oxide may have a refractive index of at least 1.6 or an extinction coefficient of at least 0.5 for wavelengths less than 400 nm.

Liner 306 or 408 may have a thickness of approximately 200˜3000 Angstroms and may be formed using chemical vapor deposition (CVD) techniques such as plasma-enhanced CVD (PECVD) or high-density plasma chemical vapor deposition (HDPCVD). A source gas combination of SiH₄ and O₂, SiH₄ and N₂O, TEOS and O₂, or TEOS and O₃ may be used in the CVD process, and the flow rates of the gases may be controlled to obtain a desirable silicon-to-oxygen ratio.

As an example, liner 306 or 408 may be formed to a thickness of approximately 1000 Angstroms by CVD using a source gas combination of SiH₄ and O₂ mixed in Ar, in which flow rates of SiH₄, O₂, and Ar are respectively 100 sccm (standard cubic centimeters per minute), 50 sccm, and 50 sccm, and an RF power of the CVD is 3000 W. In other words, the ratio of the SiH₄ flow rate to O₂ flow rate is 2. An oxide formed under such conditions has an index of refraction of approximately 1.5 and an extinction coefficient of approximately 1.7 at a wavelength of 248 nm, and the silicon atomic concentration is more than 70%.

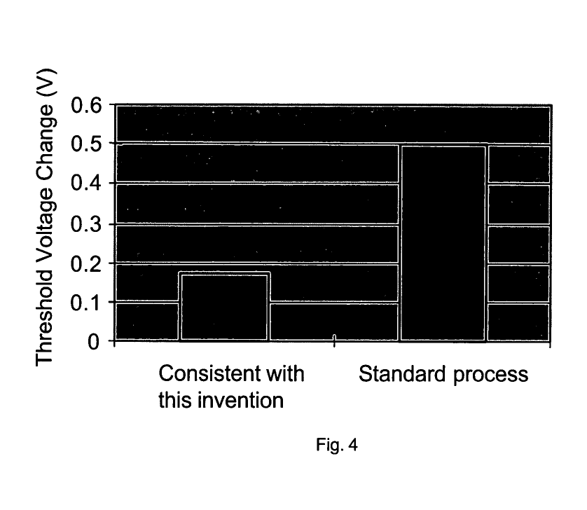

Memory devices have been manufactured using a method consistent with the present invention and measurements thereof have been performed. FIG. 4 graphically illustrates data retention properties of the manufactured memory devices as compared to standard requirements. In FIG. 4, each column indicates a change of threshold voltage after 10,000 reading cycles of a memory device, wherein the first column corresponds to a memory device manufactured by a method consistent with the present invention, and the second column shows requirements according to a standard for reference purposes. As shown in FIG. 4, the memory device formed using a method consistent with the present invention shows better data retention properties than the standard requirement.

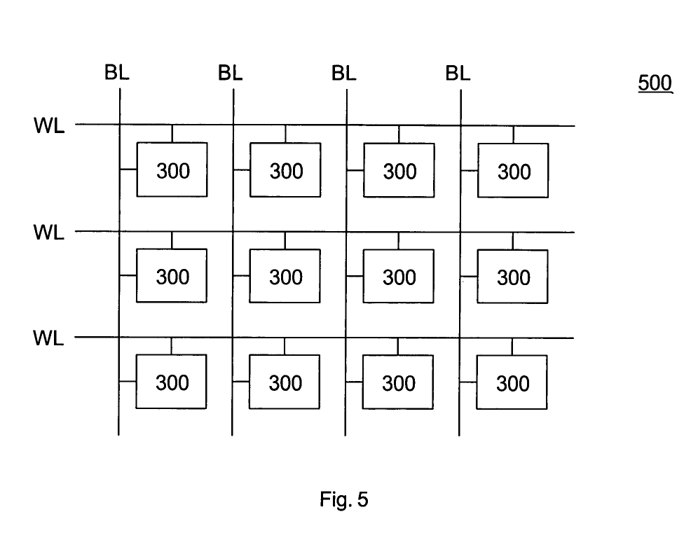

Consistent with the present invention, a plurality of memory cells having the structure of memory cell 300 or 400 may be arranged to form a memory array. FIG. 5 shows a memory array 500 consistent with the present invention. Memory array 500 includes a plurality of memory cells 300 arranged in a plurality of rows each corresponding to one of a plurality of word lines WL and a plurality of columns each corresponding to one of a plurality of bit lines BL. Also consistent with the present invention, devices such as transistors, capacitors, etc., may be formed on an integrated circuit (IC) chip together with memory cells having the structure of memory cell 300. The structure and method of constructing such memory array or IC chip should now be apparent to one skilled in the art and are not discussed in detail herein.

It will be apparent to those skilled in the art that various modifications and variations can be made in the disclosed process without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for forming a memory device, comprising:
providing a substrate;
providing a plurality of features on the substrate; and
forming a silicon-rich dielectric layer over the features.

2. The method of claim 1, further comprising forming a spin-on-glass (SOG) layer covering at least a portion of the silicon-rich dielectric layer.

3. The method of claim 1, wherein providing the plurality of features includes forming one of the features to include a multi-layered gate structure.

4. The method of claim 1, wherein providing the plurality of features includes forming one of the features to include a first metal contact.

5. The method of claim 4, further comprising
forming a spin-on-glass (SOG) layer covering at least a portion of the silicon-rich dielectric layer; and
forming a second metal contact over the SOG layer.

6. The method of claim 1, wherein forming the silicon-rich dielectric layer comprises forming a layer of silicon-rich oxide such that a ratio of a concentration of silicon atoms to a concentration of oxygen atoms therein is higher than 1:1.

7. The method of claim 1, wherein the silicon-rich dielectric layer is formed by chemical vapor deposition using at least one gas combination selected from a group consisting of a gas combination including SiH₄ and O₂, a gas combination including SiH₄ and N₂O, a gas combination including tetraethylorthosilicate (TEOS) and O₂, and a gas combination including TEOS and O₃.

8. The method of claim 1, wherein the silicon-rich dielectric layer is formed to have an extinction coefficient of at least 0.5 for wavelengths less than 400 nm.

9. The method of claim 1, wherein the silicon-rich dielectric layer is formed to have a refractive index of at least 1.6 for wavelengths less than 400 nm.

10. The method of claim 1, wherein the silicon-rich dielectric layer is formed to have a thickness of approximately 200˜3000 Angstroms.

11. The method of claim 1, wherein the silicon-rich dielectric layer is formed using plasma-enhanced chemical vapor deposition (PECVD) or high-density plasma chemical vapor deposition (HDPCVD).

12. A method for forming a semiconductor device, comprising:
providing a substrate;
forming a memory array including a plurality of memory cells over the substrate, wherein forming each of the memory cells includes
providing at least one feature over the substrate, and
forming a layer of silicon-rich dielectric over the at least one feature; and
depositing a layer of spin-on-glass to cover at least a portion of the layer of silicon-rich dielectric.

13. The method of claim 12, wherein providing the at least one feature includes
providing a first dielectric layer over the substrate,
providing a charge trapping layer over the first dielectric layer, wherein the charge trapping layer comprises polycrystalline silicon or silicon nitride,
providing a second dielectric layer over the charge trapping layer, and
providing a gate over the second dielectric layer.

14. The method of claim 12, wherein providing the at least one feature includes providing a first metal contact.

15. The method of claim 12, further comprising forming a spin-on-glass (SOG) layer covering at least a portion of the silicon-rich dielectric layer.

16. The method of claim 12, wherein forming the silicon-rich dielectric layer comprises forming a layer of silicon-rich oxide such that a ratio of a concentration of silicon atoms to a concentration of oxygen atoms therein is higher than 1:1.

17. The method of claim 12, wherein the silicon-rich dielectric layer is formed by chemical vapor deposition using at least one gas combination selected from a group consisting of a gas combination including SiH₄ and O₂, a gas combination including SiH₄ and N₂O, a gas combination including tetraethylorthosilicate (TEOS) and O₂, and a gas combination including TEOS and O₃.

18. The method of claim 12, wherein the silicon-rich dielectric layer is formed to have an extinction coefficient of at least 0.5 and a refractive index of at least 1.6 for wavelengths less than 400 nm.

19. The method of claim 12, wherein the silicon-rich dielectric layer is formed to have a thickness of approximately 200˜3000 Angstroms.

20. The method of claim 12, wherein the silicon-rich dielectric layer is formed using plasma-enhanced chemical vapor deposition (PECVD) or high-density plasma chemical vapor deposition (HDPCVD).

21. A semiconductor device, comprising:
a substrate; and
a memory cell, including
a feature over the substrate; and
a silicon-rich dielectric layer over the feature.

22. The device of claim 21, wherein the feature includes a gate structure or a metal contact.

23. The device of claim 21, further comprising a spin-on-glass (SOG) layer covering at least a portion of the silicon-rich dielectric layer.

24. The device of claim 21, wherein the silicon-rich dielectric layer comprises silicon-rich oxide having a ratio of a concentration of silicon atoms to a concentration of oxygen atoms higher than 1:1.

25. The device of claim 21, wherein the silicon-rich dielectric layer has an extinction coefficient of at least 0.5 and a refractive index of at least 1.6 for wavelengths less than 400 nm.

26. The device of claim 21, wherein the silicon-rich dielectric layer has a thickness of approximately 200˜3000 Angstroms.

27. A semiconductor device, comprising:
a substrate;
a memory array including a plurality of memory cells over the substrate, each memory cell including
a feature over the substrate, and
a layer of silicon-rich dielectric over the feature; and
a layer of spin-on-glass over the layer of silicon-rich dielectric.

28. The device of claim 27, wherein the silicon-rich dielectric layer comprises a silicon-rich oxide and a ratio of a concentration of silicon atoms to a concentration of oxygen atoms therein is higher than 1:1.

29. The device of claim 27, wherein the silicon-rich dielectric layer has an extinction coefficient of at least 0.5 and a refractive index of at least 1.6 for wavelengths less than 400 nm.

30. The device of claim 27, wherein the silicon-rich dielectric layer has a thickness of approximately 200˜3000 Angstroms.
